(19) United States
(12) Patent Application Publication
(10) Pub. No.: US 2005/0180584 A1
(43) Pub. Date: Aug. 18, 2005

(54) Speaker apparatus

(76) Inventors: Eric Y. Chin, Irvine, CA (US); Steven Chen, Irvine, CA (US)

Correspondence Address: J C PATENTS, INC., 4 VENTURE, SUITE 250, IRVINE, CA, 92618, US

(21) Appl. No.: 10/832,703

(22) Filed: Apr. 26, 2004

(30) Foreign Application Priority Data
Feb. 16, 2004 (TW) 93202168

(51) Int. Cl. H03G 5/00; H04B 3/00

(52) U.S. Cl. 381/98; 381/77

(57) ABSTRACT

A speaker apparatus having an audio frequency input interface, a control circuit, a plurality of sounders, and a plurality of luminants is provided. Wherein, after an audio frequency signal is input from the audio frequency input interface, the input signal is amplified by the control circuit and then output to the sounders. The sounders generate sounds according to the signal output from the control circuit. In addition, each sounder also corresponds to a luminant. The corresponding luminant is illuminated while the sounder is sounding. Therefore, the speaker apparatus of the present invention provides fancy visual effects while playing the sounds.

### CROSS-REFERENCE TO RELATED APPLICATION

This application claims the priority benefit of Taiwan application serial no. 93202168, filed on Feb. 16, 2004.

### BACKGROUND OF THE INVENTION

1. Field of the Invention

The present invention relates to a speaker apparatus, and more particularly, to a speaker apparatus having a luminant.

2. Description of Related Art

With great progress of the game system (e.g. TV game system), both hardware (e.g. processing speed of the game system) and software (e.g. screen outlook of the game) have been greatly improved recently, which makes market of the game system prosperous.

In order to provide more attractive audio and visual effects for the games it developed, all game vendors design the specific audio effect for each different screen in the game. Since appropriate audio effect makes the game more attractive and also improves the behavior of the game, the game vendors have put a lot of efforts on its development. In addition, the game vendor also advises the user to use better hardware equipment to play the audio effects provided by the game in order to fully enjoy the audio effects. There are various types of the hardware device for processing the audio effect, such as an audio card or a speaker apparatus, and the like, and the speaker apparatus is the object to be discussed in the present invention.

The function provided by the conventional speaker apparatus is so simple, it is only used for playing sounds and does not support other fancy functions. Even though the function of only playing sounds is good enough for the conventional speaker apparatus. However, if it is used in the modern game system, especially in the dynamic style game, such as a gun shooting game, the user will not be able to feel the reality feeling provided by the game.

### SUMMARY OF THE INVENTION

In the light of the preface, the present invention is related to a speaker apparatus for supporting strong audio and visual effects so as to create more fun for the user when playing the game.

According to an aspect of the present invention, the speaker apparatus provides the user the reality feeling effects of the game.

In an embodiment of the present invention, the speaker apparatus comprises an audio frequency input interface, a control circuit, a main sounder, a first nonlinear amplifier, and a main luminant. The audio frequency input interface receives an audio frequency signal provided by a specific audio source, and transmits the audio frequency signal to the control circuit. The control circuit comprises a main audio frequency output terminal, and it is operated by the power provided by a power supply. The control circuit amplifies the input audio frequency signal, and the amplified signal is propagated from the main audio frequency output terminal. The main sounder electrically coupled to the main audio frequency output terminal of the control circuit generates sound according to the audio frequency signal. In addition, the main audio frequency output terminal is further electrically coupled to an input terminal of the first nonlinear amplifier, such that the first nonlinear amplifier can nonlinearly amplify the signal provided by the main audio frequency output terminal so as to generate a first nonlinear signal. Moreover, an output terminal of the first nonlinear amplifier is electrically coupled to the main luminant, such that the main luminant can generate light according to the first nonlinear signal.

More specifically, the control circuit further comprises a first audio frequency output terminal, a second audio frequency output terminal, a third audio frequency output terminal, a fourth audio frequency output terminal and a bass audio frequency output terminal. In addition, the audio frequency output terminals mentioned above correspond to a first sounder, a second sounder, a third sounder, a fourth sounder, and a bass sounder, respectively. The first sounder generates sound according to a first audio channel of the audio frequency signal; the second sounder generates sound according to a second audio channel of the audio frequency signal; the third sounder generates sound according to a third audio channel of the audio frequency signal; the fourth sounder generates sound according to a fourth audio channel of the audio frequency signal; and the bass sounder generates sound according to a bass audio channel of the audio frequency signal. Moreover, the speaker apparatus of the present invention further comprises a second nonlinear amplifier and a third nonlinear amplifier. Wherein, the second nonlinear amplifier nonlinearly amplifies the signals provided by the first audio channel output terminal, the second audio channel output terminal, the third audio channel output terminal, and the fourth audio channel output terminal, so as to generate a second nonlinear signal. The third nonlinear amplifier nonlinearly amplifies a signal provided by the bass audio channel output terminal, so as to generate a third nonlinear signal.

Moreover, the speaker apparatus of the present invention further comprises a bass luminant and a plurality of sub ruminants. Wherein, the bass luminant electrically coupled to an output terminal of the third nonlinear amplifier generates light according to the third nonlinear signal, and all of the sub luminants electrically coupled to an output terminal of the second nonlinear amplifier generate light according to the second nonlinear signal.

In general, each of the main ruminant, the sub luminants, and the bass luminant mentioned above is a Light Emitting Diode (LED).

In an embodiment of the present invention, the control circuit comprises a demultiplexer, an electronic volume controller, a first amplifier, a user input module, and a controller. After the audio frequency signal transmitted from the audio frequency input interface is received by the control circuit, it is further transmitted to the electronic volume controller and the controller via the demultiplexer. Wherein, the electronic volume controller electrically coupled to the demultiplexer and the first amplifier controls volume of the sound output from the speaker apparatus of the present invention. The first amplifier comprises the main audio frequency output terminal mentioned above for outputting a main audio channel of the audio frequency signal. The first amplifier determines a volume of the sound output from the main sounder according to an output of the electronic volume controller. In addition, the controller electrically couples to the demultiplexer and the user input module. The user input module serves as an operation interface between the user and the present invention, such that the user can control the speaker apparatus of the present invention by operating the user input module. Therefore, the controller controls the output of the demultiplexer according to the user operation. Moreover, the controller controls the electronic volume controller to determine the volume of the sound output from the speaker apparatus of the present invention according to the user operation and the demultiplexer output.

In addition, the control circuit further comprises a second amplifier and a third amplifier. The second amplifier comprises the first audio frequency output terminal, the second audio frequency output terminal, the third audio frequency output terminal, and the fourth audio frequency output terminal mentioned above, and the third amplifier comprises the bass audio frequency output terminal mentioned above. Wherein, the second amplifier determines the volume of the sound output from the first sounder, the second sounder, the third sounder, and the fourth sounder according to the output of the electronic volume controller. Similarly, the third amplifier determines the volume of the sound output from the bass sounder according to the output from the electronic volume controller.

Moreover, the control circuit further comprises a rectifier. The rectifier receives electricity provided by the power supply, rectifies the electricity, and sends the rectified electricity to the demultiplexer, the user input module, the controller, the electronic volume controller, the first amplifier, the second amplifier, and the third amplifier. The user controls the rectifier through the user input module to determine whether the speaker apparatus of the present invention is powered on or not.

In the embodiment of the present invention, the demultiplexer mentioned above comprises a first demultiplexer and a second demultiplexer. Both demultiplexers are electrically coupled to the audio frequency input interface for transmitting the audio frequency signal to the controller and the electronic volume controller.

Under normal situation, the power supply electrically coupled to the control circuit is further electrically coupled to an external AC power via a transformer.

According to another embodiment of the present invention, the speaker apparatus comprises an audio frequency input interface and a control circuit. Wherein, the audio frequency input interface electrically coupled to a specific audio source receives an audio frequency signal provided by the audio source and transmits the received audio frequency signal to the control circuit. The control circuit receives electricity provided by a power supply for amplifying and outputting the received audio frequency signal. In addition, the control circuit comprises a main audio frequency output terminal, a first audio frequency output terminal, a second audio frequency output terminal, a third audio frequency output terminal, a fourth audio frequency output terminal, and a bass audio frequency output terminal. Moreover, the audio frequency output terminals mentioned above are electrically coupled to a main sounder, a plurality of sub sounders, and a bass sounder, respectively. Wherein, the main sounder electrically coupled to the main audio frequency output terminal generates sound according to a main audio channel of the audio frequency signal. The sub sounders respectively electrically coupled to the first audio frequency output terminal, the second audio frequency output terminal, the third audio frequency output terminal, and the fourth audio frequency output terminal generate sounds according to the first audio channel, the second audio channel, the third audio channel, and the fourth audio channel of the audio frequency signal. The bass sounder electrically coupled to the bass audio frequency output terminal generates sound according to the bass audio channel of the audio frequency signal. Moreover, the present invention further comprises a main luminant, a bass luminant, and a plurality of sub luminants. Wherein, the main luminant electrically coupled to the main audio frequency output terminal generates light according to the main audio channel of the audio frequency signal. The bass luminant electrically coupled to the bass audio frequency output terminal generates light according to the bass audio channel of the audio frequency signal. The sub luminants respectively electrically coupled to the first audio frequency output terminal, the second audio frequency output terminal, the third audio frequency output terminal, and the fourth audio frequency output terminal generate lights according to the first audio channel, the second audio channel, the third audio channel, and the fourth audio channel of the audio frequency signal.

In an embodiment of the present invention, the sub luminants mentioned above comprise a first luminant, a second luminant, a third luminant, and a fourth luminant. Wherein, the first luminant electrically coupled to the first audio frequency output terminal generates light according to the first audio channel of the audio frequency signal; the second luminant electrically coupled to the second audio frequency output terminal generates light according to the second audio channel of the audio frequency signal; the third luminant electrically coupled to the third audio frequency output terminal generates light according to the third audio channel of the audio frequency signal; and the fourth luminant electrically coupled to the fourth audio frequency output terminal generates light according to the fourth audio channel of the audio frequency signal.

In addition, the sub sounders comprise a first sounder, a second sounder, a third sounder, and a fourth sounder. Wherein, the first sounder electrically coupled to the first audio frequency output terminal generates sound according to the first audio channel of the audio frequency signal; the second sounder electrically coupled to the second audio frequency output terminal generates sound according to the second audio channel of the audio frequency signal; the third sounder electrically coupled to the third audio frequency output terminal generates sound according to the third audio channel of the audio frequency signal; and the fourth sounder electrically coupled to the fourth audio frequency output terminal generates sound according to the fourth audio channel of the audio frequency signal.

In summary, since the present invention provides a plurality of sounders, it makes the audio effect finer, and allows the user enjoy the reality feeling when playing the game. In addition, the present invention further comprises a plurality of luminants, which is used to generate lights according to the output audio effects. Therefore, the present invention is not only used to play audio effects, but also to provide more fancy visual effects, so as to create more fun for the user while playing the game.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1 is a schematic block diagram of a speaker apparatus according to a first embodiment of the present invention.

FIG. 2 is a schematic block diagram of a speaker apparatus according to a second embodiment of the present invention.

FIG. 3 is a schematic block diagram of a speaker apparatus according to a third embodiment of the present invention.

### DESCRIPTION OF THE EMBODIMENTS

### First Embodiment

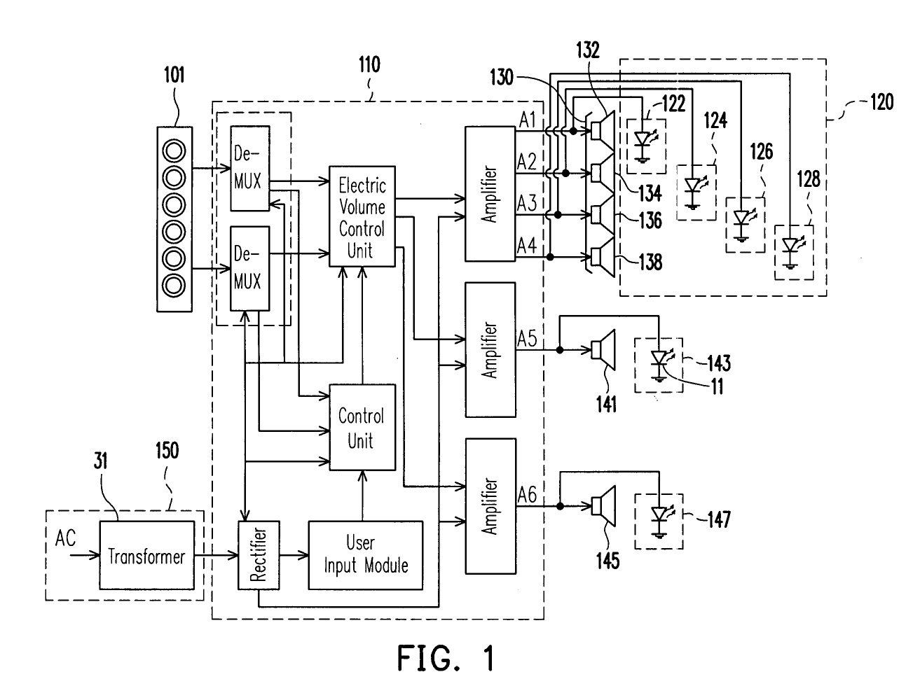

FIG. 1 is a schematic block diagram of a speaker apparatus according to a first embodiment of the present invention. Referring to FIG. 1, an audio frequency input interface 101 receives an audio frequency signal provided by a specific audio source (e.g. a TV game system), and transmits the received audio frequency signal to a control circuit 110. The control circuit 110 electrically coupled to a power supply 150 amplifies the signal received from the audio frequency input interface 101 and transmits the amplified signal to a main sounder 141, a bass sounder 145, and a plurality of sub sounders 130. In general, the electricity provided by the power supply 150 may be the electricity provided by an AC power AC via a transformer 31. In addition, the control circuit 110 further electrically couples to a main luminant 143, a bass luminant 147, and a plurality of sub luminants 120. In the present embodiment, each of the luminants may be an LED 11.

The control circuit 110 comprises a first audio frequency output terminal A1, a second audio frequency output terminal A2, a third audio frequency output terminal A3, a fourth audio frequency output terminal A4, a main audio frequency output terminal A5, and a bass audio frequency output terminal A6. In addition, the audio frequency output terminals mentioned above respectively transmit a first audio channel, a second audio channel, a third audio channel, a fourth audio channel, a main audio channel, and a bass audio channel of the audio frequency signal received from the control circuit 110 to the sub sounders 130, the main sounder 141, and the bass sounder 145.

In the present embodiment, the sub sounders 130 comprise a first sounder 132, which electrically couples to the first audio frequency output terminal A1 and generates sound according to the first audio channel of the audio frequency signal; a second sounder 134, which electrically couples to the second audio frequency output terminal A2 and generates sound according to the second audio channel of the audio frequency signal; a third sounder 136, which electrically couples to the third audio frequency output terminal A3 and generates sound according to the third audio channel of the audio frequency signal; and a fourth sounder 138, which electrically couples to the fourth audio frequency output terminal A4 and generates sound according to the fourth audio channel of the audio frequency signal. In addition, the main sounder 141 electrically coupled to the main audio frequency output terminal A5 generates sound according to the main audio channel of the audio frequency signal, and the bass sounder 145 electrically coupled to the bass audio frequency output terminal A6 generates sound according to the bass audio channel of the audio frequency signal.

Moreover, the sub luminants 120 corresponding to the sub sounders 130 comprise a first luminant 122, which is electrically coupled to the first audio frequency output terminal A1; a second luminant 124, which is electrically coupled to the second audio frequency output terminal A2; a third luminant 126, which is electrically coupled to the third audio frequency output terminal A3; and a fourth luminant 128, which is electrically coupled to the fourth audio frequency output terminal A4. In addition, the main luminant 143 is electrically coupled to the main audio frequency output terminal A5, and the bass luminant 147 is electrically coupled to the bass audio frequency output terminal A6.

All of the luminants mentioned above are driven by the signal output from the output terminal it electrically couples to generate lights. More specifically, for example, while the bass sounder 145 generates audio effect according to the bass audio channel of the audio frequency signal, the bass luminant 147 is also driven by the bass audio channel of the audio frequency signal to generate light. Therefore, the way that the bass luminant 147 generates light is based on the rhythm of the bass audio frequency in the audio frequency signal. In other words, the brightness of the light generated by the bass luminant 147 is varied according to different magnitude of the bass audio channel in the audio frequency signal.

In the present embodiment, the speaker apparatus of the present invention uses 6 sounders to perform 6 different audio channels of the audio frequency signal. Therefore, the user can feel reality when the speaker apparatus of the present invention is used in playing the game.

In addition, in the present embodiment, each sounder further corresponds to a separate luminant. While the sounder is generating a sound, the corresponding luminant is also illuminated. Therefore, while the speaker apparatus of the present invention is sounding, a fancy visual effect is also provided by light illumination.

### Second Embodiment

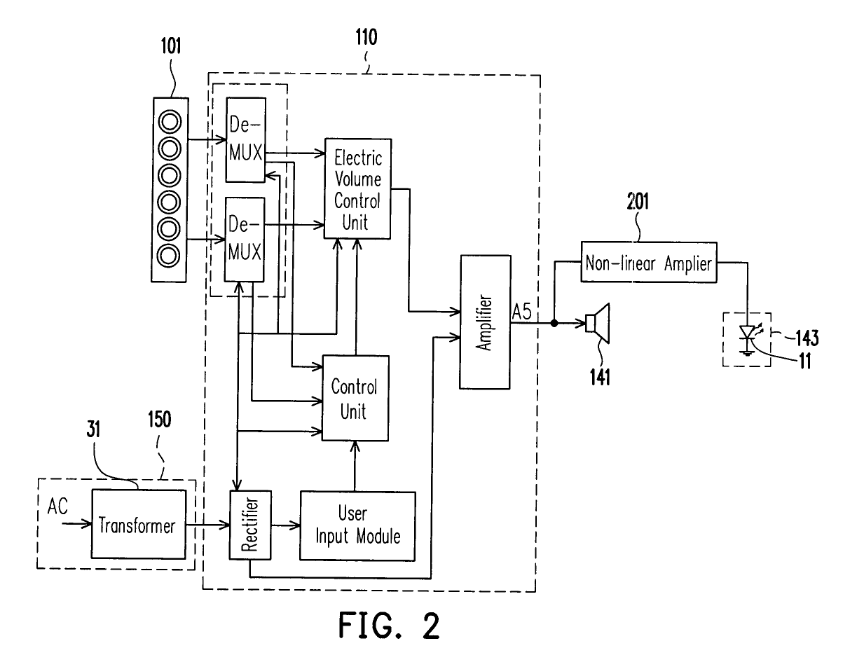

FIG. 2 is a schematic block diagram of a speaker apparatus according to a second embodiment of the present invention. Referring to FIG. 2, in order to make the visual effect of the previous embodiment more obvious, in the present embodiment, the main audio frequency output terminal A5 is further electrically coupled to a nonlinear amplifier 201, and an output terminal of the nonlinear amplifier 201 is electrically coupled to the luminant 143. Therefore, after the audio frequency signal is propagated from the main audio frequency output terminal A5, it is nonlinearly amplified by the nonlinear amplifier 201 so as to generate a nonlinear signal, and the main luminant 143 generates light according to the nonlinear signal. The nonlinear amplification operation means the magnitude of the signal output from the main audio frequency output terminal A5 is not linear with the amplification ratio. In other words, the smaller the signal output from the main audio frequency output terminal A5, the bigger the nonlinear signal generated from the amplification operation performed by the nonlinear amplifier 201. Contrarily, the bigger the signal output from the main audio frequency output terminal A5, the smaller the amplification ratio of the nonlinear amplifier 201.

In general, the luminant 143 generally uses an LED 11 as its light source. The condition for the LED 11 to illuminate is that the LED 11 illuminates only when the magnitude of the input signal is higher than the threshold voltage of the LED 11. In the present embodiment, since the main audio frequency output terminal A5 is electrically coupled to the nonlinear amplifier 201, even the signal output from the main audio frequency output terminal A5 is very small, the nonlinear signal generated from the nonlinear amplification operation by the nonlinear amplifier 201 is still higher than the threshold voltage of the LED 11, thus it can drive the LED 11 to illuminate.

### Third Embodiment

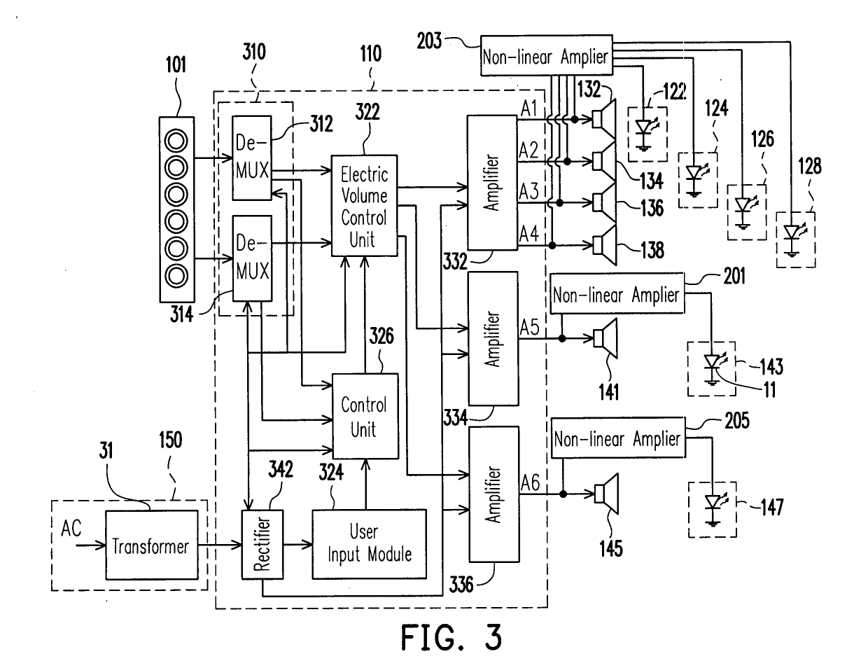

In another embodiment of the present invention, the speaker apparatus of FIG. 1 may be designed as the speaker apparatus shown in FIG. 2. FIG. 3 is a schematic block diagram of a speaker apparatus according to a third embodiment of the present invention. Referring to FIG. 3, in the present embodiment, besides the main audio frequency output terminal A5 is electrically coupled to the nonlinear amplifier 201, the bass audio frequency output terminal A6 is also electrically coupled to the nonlinear amplifier 205, and the first audio frequency output terminal A1, the second audio frequency output terminal A2, the third audio frequency output terminal A3, and the fourth audio frequency output terminal A4 are further electrically coupled to the nonlinear amplifier 203. Wherein, an output terminal of the nonlinear amplifier 205 is electrically coupled to the luminant 147, and an output terminal of the nonlinear amplifier 203 is electrically coupled to the luminants 122, 124, 126, and 128. Moreover, the operating principle of the nonlinear amplifiers 203 and 205 are the same as the operating principle of the nonlinear amplifier 201 in the second embodiment, thus its detail is omitted herein.

The operating principle of the control circuit 110 in the first, second, and third embodiments mentioned above are all the same, thus only the control circuit 110 of FIG. 3 is exemplified herein for description. Referring to FIG. 3, the demultiplexer 310 receives the audio frequency signal propagated from the audio frequency input interface 101, and the demultiplexer 310 transmits the signal it outputs to the electronic volume controller 322 and the controller 326. The electronic volume controller 322 electrically couples to the amplifiers 332, 334, and 336. In addition, the rectifier 342 receives electricity provided by the power supply 150, rectifies the electricity, and transmits the rectified electricity to the demultiplexer 310, the electronic volume controller 322, the user input module 324, the controller 326, and the amplifiers 332, 334, and 336. Wherein, the user input module 324 is electrically coupled to the controller 326.

In the present embodiment, the demultiplexer 310 may comprise demultiplexers 312 and 314. The inputs of the demultiplexers 312 and 314 are electrically coupled to the audio frequency input interface 101, and its outputs are electrically coupled to the electronic volume controller 322 and the controller 326. Wherein, the electronic volume controller 322 controls the volume of the sound output from the speaker apparatus of the present invention. Therefore, the electronic volume controller 322 adjusts the volume of the sound signal output from the demultiplexer, and transmits the signal to the amplifiers 332, 334, and 336. The amplifiers 332, 334, and 336 work together to determine the volume of the sound output from the first sounder 132, the second sounder 134, the third sounder 136, the fourth sounder 138, the main sounder 141, and the bass sounder 145.

The functions of the amplifiers 332, 334, and 336 are described with referring to FIG. 3 hereinafter. The amplifier 332 is a 1-to-4 amplifier comprising a first audio frequency output terminal A1, a second audio frequency output terminal A2, a third audio frequency output terminal A3, and a fourth audio frequency output terminal A4. The amplifier 332 respectively amplifies the first audio channel, the second audio frequency, the third audio frequency, and the fourth audio frequency of the audio frequency signal, and transmits the amplified signals to the first sounder 132, the second sounder 134, the third sounder 136, and the fourth sounder 138 through different audio frequency output terminals, so as to make different sounds. The amplifier 334 amplifies the main audio channel of the audio frequency signal, and comprises a main audio frequency output terminal A5 for propagating the main audio channel of the audio frequency signal. The amplifier 336 amplifies the bass audio channel of the audio frequency signal and the amplified signal is propagated from a bass audio frequency output terminal A6, such that the bass sounder 145 can make a sound.

Referring to FIG. 3, the user input module 324 may be composed of a plurality of operating keys. The user controls the speaker apparatus of the present invention by operating the user input module 324, for example, performing the operation of controlling the volume tuning or the power switching. The output of the user input module 324 is electrically coupled to the controller 326, thus when the user inputs the instructions via the user input module 324, the controller 326 can control the speaker apparatus of the present invention according to the instruction input by the user, for example, to control the rectifier 342 to power on or power off the speaker apparatus of the present invention, or to control the electronic volume controller 322 to adjust the volume of the sound output from the speaker apparatus of the present invention. Moreover, the controller 326 switches the output of the demultiplexer 310 according to the instruction input by the user, and the controller 326 controls the electronic volume controller 322 according to the output of the demultiplexer 310.

In summary, the present invention at least has following advantages:
1. The present invention uses 6 sounders to generate sounds, such that the fineness of the sound is increased.
2. In the present invention, a corresponding luminant is illuminated while each of the sounders is sounding. Therefore, the present invention not only plays sounds, but also provides fancy visual effect.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

1. A speaker apparatus, comprising:
an audio frequency input interface, electrically coupled to an audio source for receiving an audio frequency signal generated by the audio source;
a control circuit having a main audio frequency output terminal, wherein the control circuit is electrically coupled to the audio frequency input interface and a power supply amplifies the audio frequency signal, and the amplified audio frequency signal is propagated from the main audio frequency output terminal;
a main sounder, electrically coupled to the main audio frequency output terminal for generating a sound according to the audio frequency signal;
a first nonlinear amplifier, whose input terminal is electrically coupled to the main audio frequency output terminal is adapted for nonlinearly amplifying the signal output from the main audio frequency output terminal so as to generate a first nonlinear signal; and
a main luminant, electrically coupled to an output terminal of the first nonlinear amplifier for generating a light according to the first nonlinear signal.

2. The speaker apparatus of claim 1, wherein the control circuit further comprises a first audio frequency output terminal, a second audio frequency output terminal, a third audio frequency output terminal, a fourth audio frequency output terminal, and a bass audio frequency output terminal, and the speaker apparatus further comprises:
a first sounder, electrically coupled to the first audio frequency output terminal for generating a sound according to a first audio channel of the audio frequency signal;
a second sounder, electrically coupled to the second audio frequency output terminal for generating a sound according to a second audio channel of the audio frequency signal;
a third sounder, electrically coupled to the third audio frequency output terminal for generating a sound according to a third audio channel of the audio frequency signal;
a fourth sounder, electrically coupled to the fourth audio frequency output terminal for generating a sound according to a fourth audio channel of the audio frequency signal;
a bass sounder, electrically coupled to the bass audio frequency output terminal for generating a sound according to a bass audio channel of the audio frequency signal;
a second nonlinear amplifier, for nonlinearly amplifying a plurality of signals output from the first audio frequency output terminal, the second audio frequency output terminal, the third audio frequency output terminal, and the fourth audio frequency output terminal so as to generate a second nonlinear signal; and
a third nonlinear amplifier, for nonlinearly amplifying a signal output from the bass audio frequency output terminal so as to generate a third nonlinear signal.

3. The speaker apparatus of claim 2, further comprising:
a plurality of sub luminants, electrically coupled to an output terminal of the second nonlinear amplifier for generating a light according to the second nonlinear signal; and
a bass luminant, electrically coupled to an output terminal of the third nonlinear amplifier for generating a light according to the third nonlinear signal.

4. The speaker apparatus of claim 3, wherein each of the main luminant, the sub luminants, and the bass luminant is an LED.

5. The speaker apparatus of claim 2, wherein the control circuit further comprises:
a demultiplexer, electrically coupled to the audio frequency input interface for receiving the audio frequency signal;
an electronic volume controller, electrically coupled to the demultiplexer for controlling a volume of a sound output from the speaker apparatus;
a first amplifier having the main audio frequency output terminal for propagating a main audio channel of the audio frequency signal, and the first amplifier determining a volume of a sound output from the main sounder according to an output of the electronic volume controller;
a user input module, wherein a user controls the speaker apparatus by operating the user input module; and
a controller, for controlling an output of the demultiplexer according to the user operation, and also for controlling the electronic volume controller to determine the volume of the sound output from the speaker apparatus according to the user operation and the demultiplexer output.

6. The speaker apparatus of claim 5, wherein the control circuit further comprises:
a second amplifier having the first audio frequency output terminal, the second audio frequency output terminal, the third audio frequency output terminal, and the fourth audio frequency output terminal, for determining the volume of the sound output from the first sounder, the second sounder, the third sounder, and the fourth sounder according to the output of the electronic volume controller; and
a third amplifier having the bass audio frequency output terminal, for determining the volume of the sound output from the bass sounder according to the output from the electronic volume controller.

7. The speaker apparatus of claim 6, wherein the control circuit further comprises a rectifier electrically coupled to the power supply for rectifying an electricity provided by the power supply, transmitting the rectified electricity to the demultiplexer, the user input module, the controller, the electronic volume controller, the first amplifier, the second amplifier, and the third amplifier, and the user controls the rectifier via the user input module so as to determine whether the speaker apparatus is powered on or not.

8. The speaker apparatus of claim 5, wherein the demultiplexer comprises:
a first demultiplexer, electrically coupled to the audio frequency input interface and
a second demultiplexer, electrically coupled to the audio frequency input interface,
wherein, the first demultiplexer and the second demultiplexer transmit the audio frequency signal to the controller and the electronic volume controller.

9. The speaker apparatus of claim 1, wherein the power supply is an AC power which is supplied to the control circuit via a transformer.

10. A speaker apparatus, comprising:
an audio frequency input interface, electrically coupled to an audio source for receiving an audio frequency signal generated by the audio source;
a control circuit having a main audio frequency output terminal, a second audio frequency output terminal, a third audio frequency output terminal, a fourth audio frequency output terminal, and a bass audio frequency output terminal, the control circuit being electrically coupled to the audio frequency input interface and a power supply for amplifying and propagating the audio frequency signal;
a main sounder, electrically coupled to the main audio frequency output terminal for generating a sound according to a main audio channel of the audio frequency signal;
a bass sounder, electrically coupled to the bass audio frequency output terminal for generating a sound according to a bass audio channel of the audio frequency signal;
a plurality of sub sounders, respectively electrically coupled to the first audio frequency output terminal, the second audio frequency output terminal, the third audio frequency output terminal, and the fourth audio frequency output terminal, the sub sounders generating a plurality of sounds according to a first audio channel, a second audio channel, a third audio channel, and a fourth audio channel of the audio frequency signal;
a main luminant, electrically coupled to the main audio frequency output terminal for generating a light according to the main audio channel of the audio frequency signal;
a bass luminant, electrically coupled to the bass audio frequency output terminal for generating a light according to the bass audio channel of the audio frequency signal; and
a plurality of sub luminants, respectively electrically coupled to the first audio frequency output terminal, the second audio frequency output terminal, the third audio frequency output terminal, and the fourth audio frequency output terminal, the sub luminants generating a plurality of lights according to the first audio channel, the second audio channel, the third audio channel, and the fourth audio channel of the audio frequency signal.

11. The speaker apparatus of claim 10, wherein the sub luminants comprise:
a first luminant, electrically coupled to the first audio frequency output terminal for generating a light according to the first audio channel of the audio frequency signal;
a second luminant, electrically coupled to the second audio frequency output terminal for generating a light according to the second audio channel of the audio frequency signal;
a third luminant, electrically coupled to the third audio frequency output terminal for generating a light according to the third audio channel of the audio frequency signal; and
a fourth luminant, electrically coupled to the fourth audio frequency output terminal for generating a light according to the fourth audio channel of the audio frequency signal.

12. The speaker apparatus of claim 10, wherein the sub sounders comprise:
a first sounder, electrically coupled to the first audio frequency output terminal for generating a sound according to the first audio channel of the audio frequency signal;
a second sounder, electrically coupled to the second audio frequency output terminal for generating a sound according to the second audio channel of the audio frequency signal;
a third sounder, electrically coupled to the third audio frequency output terminal for generating a sound according to the third audio channel of the audio frequency signal; and
a fourth sounder, electrically coupled to the fourth audio frequency output terminal for generating a sound according to the fourth audio channel of the audio frequency signal.

13. The speaker apparatus of claim 10, wherein each of the main luminant, the bass luminant, and the sub luminants is an LED.
